(19) United States
(12) Patent Application Publication
(10) Pub. No.: US 2019/0082527 A1
(43) Pub. Date: Mar. 14, 2019

(54) CIRCUIT STRUCTURE

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(72) Inventor: Yukinori KITA, Mie (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 16/084,819

(22) PCT Filed: Mar. 16, 2017
(86) PCT No.: PCT/JP2017/010576

§ 371 Date: Sep. 13, 2018

(30) Foreign Application Priority Data
Mar. 30, 2016 (JP) 2016-067442

(51) Int. Cl. H05K 1/02; H05K 7/20; H05K 1/18

(52) U.S. Cl. CPC H05K 1/0207; H05K 1/181; H05K 7/205

(57) ABSTRACT

A circuit structure including: an electronic component including a lower surface electrode; a circuit board including a first circuit and a second circuit; and a thermally conductive conducting member to be disposed between the lower surface electrode of the electronic component and the first circuit. The thermally conductive conducting member includes an electronic component connection portion to be conductively connected to the lower surface electrode of the electronic component, a first circuit connection portion to be conductively connected to the first circuit, and a second circuit connection portion to be conductively connected to the second circuit.

### TECHNICAL FIELD

The technique disclosed herein relates to a circuit structure.

### BACKGROUND ART

Conventionally, the circuit structure described in JP 2016-25229A (Patent Document 1 below) is known as a circuit structure including a substrate on which an electronic component is to be mounted, and a conductive member fixed to a lower surface of the substrate. A first opening extending through the substrate in the thickness direction is formed at a position of the substrate at which the electronic component is to be mounted. The conductive member faces upward in the first opening face, and a third type terminal of the electronic component is soldered to the conductive member through the first opening. In addition, a second opening that allows a protruding portion formed on the conductive member to be exposed upward is formed in the substrate. A second type terminal of the electronic component is soldered to the protruding portion through the second opening. Note that a first type terminal of the electronic component is soldered to a land formed on an upper surface of the substrate.

### CITATION LIST

### Patent Document

Patent Document 1: JP 2016-25229A

### SUMMARY

### Technical Problem

In recent years, electronic components are increasingly becoming smaller, and the area of the soldered portion between the third type terminal of an electronic component and the conductive member is also being reduced accordingly. However, the amount of heat generated in an electronic component even with a reduced size is not significantly different from that of the conventional electronic component. Accordingly, the amount of heat generated at the soldered portion per unit area increases, making further enhancement of the heat dissipation performance imperative.

### Solution to Problem

A circuit structure disclosed herein is a circuit structure including: an electronic component including a lower surface electrode; a circuit board including a first circuit and a second circuit; and a thermally conductive conducting member to be disposed between the lower surface electrode of the electronic component and the first circuit, wherein the thermally conductive conducting member includes an electronic component connection portion to be conductively connected to the lower surface electrode of the electronic component, a first circuit connection portion to be conductively connected to the first circuit, and a second circuit connection portion to be conductively connected to the second circuit.

With this configuration, the lower surface electrode of the electronic component is conductively connected to the first circuit via the thermally conductive conducting member, and is also conductively connected to the second circuit. Since the heat generated in the electronic component dissipates to both the first circuit and the second circuit via the thermally conductive conducting member, it is possible to enhance the heat dissipation performance compared with that achieved by dissipating heat only to the first circuit as in the conventional technique, Therefore, it is possible to ensure the heat dissipation performance even for an electronic component with a reduced size.

The circuit structure disclosed herein may have the following configuration.

The first circuit may be disposed on a first surface of the circuit board, the second circuit may be disposed on a second surface of the circuit board, and the circuit board may have a first opening that allows the first circuit to be exposed on the second surface side, and the first circuit connection portion may be provided so as to extend along the first circuit inside the first opening.

This configuration facilitates mounting of the thermally conductive conducting member to the circuit board since it is only necessary to place the first circuit connection portion of the thermally conductive conducting member on the first circuit exposed in the first opening.

The second circuit connection portion may be provided so as to extend along the second surface of the circuit board, and the first circuit connection portion and the second circuit connection portion may be connected to each other via an intermediate connection portion.

This configuration facilitates mounting of the thermally conductive conducting member to the circuit board since it is only necessary to place the second circuit connection portion on the second circuit.

The intermediate connection portion may have a crank-like shape extending from the first circuit, through a peripheral edge portion of the first opening, to the second circuit.

This configuration facilitates mounting of the thermally conductive conducting member to the circuit board since it is only necessary to place the intermediate connection portion so as to extend from the first circuit to the second circuit.

The circuit board may have a second opening that allows the first circuit to be exposed on the second surface side, the electronic component may include a first electrode connected to the first circuit via a relay terminal disposed in the second opening, and a second electrode to be connected to the second circuit, and the first electrode and the second electrode may be disposed at the same height in a thickness direction of the circuit board.

With this configuration, the first electrode is connected to the first circuit via the relay terminal. Accordingly, the first circuit and the second circuit can be connected without processing the first electrode to conform to the height of the first circuit, even when they have different heights. In addition, the heat generated in the electronic component dissipates to both the first circuit and the second circuit via the relay terminal, and it is therefore possible to further enhance the heat dissipation performance.

### Advantageous Effects

With the circuit structure disclosed herein, it is possible to ensure the heat dissipation performance even for an electronic component with a reduced size.

### BRIEF DESCRIPTION OF DRAWINGS

FIG. 1 is a plan view of a circuit structure according to Embodiment 1.

FIG. 2 is a side view of the circuit structure.

FIG. 3 is a cross-sectional view taken along the line A-A in FIG. 1.

FIG. 4 is a cross-sectional view taken along the line B-B in FIG. 1.

FIG. 5 is a plan view of a circuit structure according to Embodiment 2.

FIG. 6 is a side view of the circuit structure.

FIG. 7 is a cross-sectional view taken along the line C-C in FIG. 5.

FIG. 8 is a cross-sectional view of a conventional circuit structure.

### DESCRIPTION OF EMBODIMENTS

### Embodiment 1

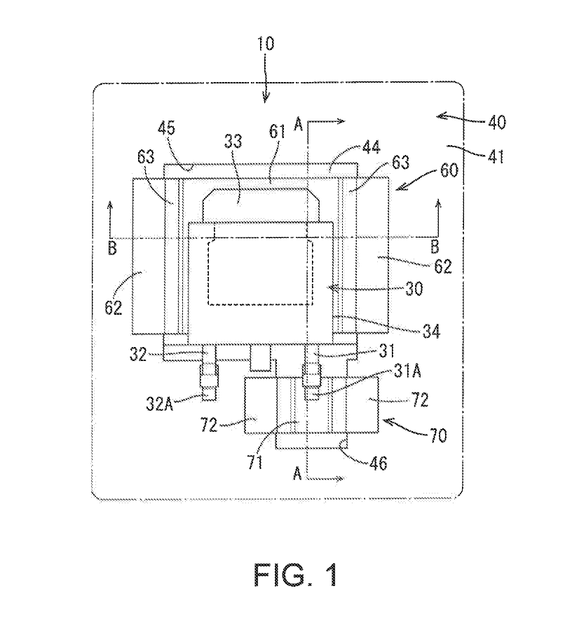

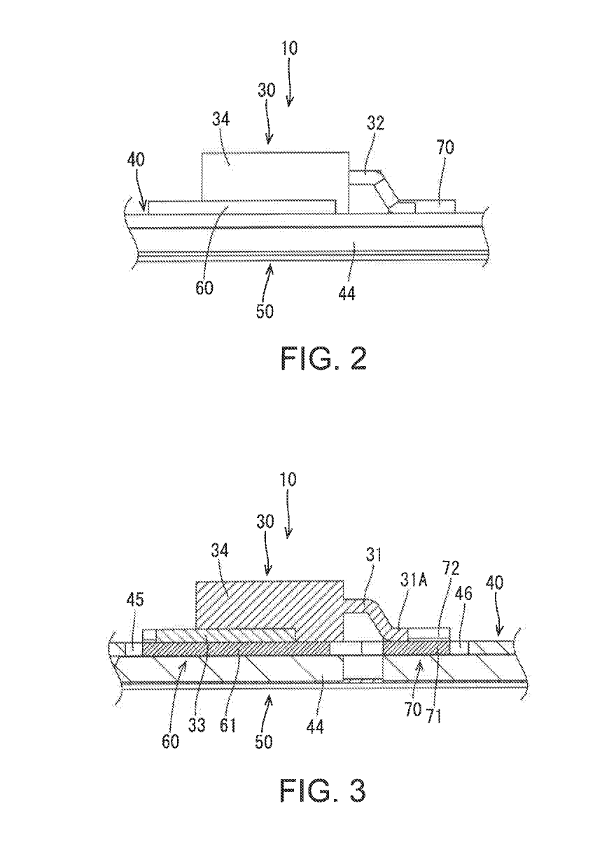

Embodiment 1 will be described with reference to FIGS. 1 to 4. A circuit structure 10 according to Embodiment 1 includes an electronic component 30, a circuit board 40 on which the electronic component 30 is to be mounted, and a base member 50 on which the circuit board 40 is to be installed. Note that unless otherwise specified, “plane direction” in the following description refers to a plane direction of the circuit board 40, and “height direction” (vertical direction) refers to a direction orthogonal to the plane direction (in which the surface of the circuit board 40 on which the electronic component 30 is mounted is the upper surface).

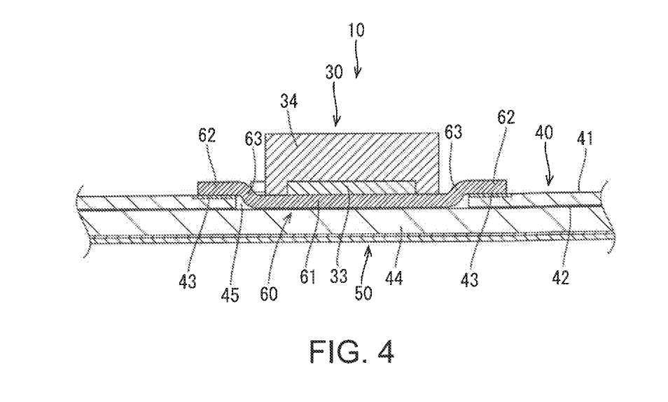

As shown in FIG. 4, a first circuit (a conductive member 44 is shown as an example in Embodiment 1) is provided on a first surface (lower surface) 42 of the circuit board 40, and a second circuit (lands 43 provided at a plurality of positions are shown as an example in Embodiment 1) is provided on a second surface (upper surface) 41 of the circuit board 40 (surfaces are opposite). The first circuit is a power circuit, and the second circuit is a control circuit.

The conductive member 44 is a plate-shaped member also called a bus bar (bus bar plate) or the like. While the conductive member 44 is formed in a predetermined shape through pressing or the like, the description and illustration of the specific configuration of the conductive member 44 have been omitted. The conductive member 44 is fixed to the first surface 42 of the circuit board 40 via an insulating adhesive sheet or the like, for example.

As shown in FIGS. 1, to 3, the electronic component 30 includes a body portion 34 in which an element is incorporated, and a terminal portion provided so as to be exposed on the outer surface of the body portion 34. In Embodiment 1, a first electrode 31, a second electrode 32, and a lower surface electrode 33 are shown as examples of the terminal portions, and the electronic component 30 in Embodiment 1 is a transistor (FET). The first electrode 31 is a source terminal, the second electrode 32 is a gate terminal, and the lower surface electrode 33 is a drain terminal. The first electrode 31 is connected to the first circuit (conductive member 44), the second electrode 32 is connected to the second circuit (lands 43), and the lower surface electrode 33 is connected to the first circuit (a position different from the first electrode 31 of the conductive member 44).

The first electrode 31 and the second electrode 32 protrude laterally from a side surface of the rectangular solid-shaped body portion 34. Specifically, the two electrodes 31 and 32 have proximal end-side portions protruding along the plane direction, portions that are bent so as to extend downward from distal ends of the proximal end-side portions, and distal end portions 31A and 32A extending from the distal ends of the bent portions so as to follow the plane direction. The heights (positions in tie vertical direction) of the distal end portions 31A and 32A, which are portions to be soldered, are set to be the same. In Embodiment 1, the first electrode 31 and the second electrode 32 are formed in exactly the same shape.

The lower surface electrode 33 is a plate-shaped portion provided on the bottom (lower surface) of the body portion 34, and has a shape following the plane direction. The lower surface of the lower surface electrode 33 and the lower surface of the body portion 34 are flush with each other. A part of the lower surface electrode 33 is located on the lower surface of the body portion 34, and the remaining part protrudes laterally from a side surface of the body portion 34. The entire lower surface of the lower surface electrode 33 constitutes a portion to be soldered to a heat spreader 60, which will be described below.

A first opening 45 is provided at a position of the circuit hoard 40 at which the body portion 34 of the electronic component 30 is to be mounted. The first opening 45 extends vertically through the circuit board 40 so as to allow the conductive member 44 disposed on the first surface 42 to be exposed on the second surface 41 side. The heat spreader 60 is connected to the upper surface of the conductive member 44 exposed in the first opening 45 through soldering, and the body portion 34 of the electronic component 30 is connected to the upper surface of the heat spreader 60 through soldering.

As shown in FIG. 4, the heat spreader 60 includes a first circuit connection portion 61 to be conductively connected to the conductive member 44 serving as the first circuit, a pair of second circuit connection portions 62 to be respectively connected to a pair of lands 43 serving as the second circuit, and a pair of intermediate connection portions 63 that each connect the first circuit connection portion 61 to the pair of second circuit connection portions 62. The heat spreader 60 is formed by pressing a metal plate of copper or the like into a predetermined shape. Accordingly, the lower surface electrode 33 of the electronic component 30 is conductively connected to the conductive member 44 serving as the first circuit via the heat spreader 60.

The first circuit connection portion 61 is provided so as to extend along the conductive member 44 inside the first opening 45. The intermediate connection portions 63 have a crank-like shape extending from the conductive member 44 serving as the first circuit, through a peripheral edge portion of the first opening 45, to the lands 43 serving as the second circuit. The lower surface of the first circuit connection portion 61 is connected to the upper surface of the conductive member 44, whereas the lower surface electrode 33 of the electronic component 30 is connected to the upper surface of the first circuit connection portion 61. That is, in Embodiment 1, the first circuit connection portion 61 to be connected to the conductive member 44 serving as the first circuit and the electronic component connection portion to be connected to the lower surface electrode 33 of the electronic component 30 are provided at the same position so as to be arranged overlapping in the vertical direction.

The lower surface of the first circuit connection portion 61 and the upper surface of the conductive member 44 are conductively connected to each other through soldering, and the upper surface of the first circuit connection portion 61 and the lower electrode 33 of the electronic component 30 are conductively connected to each other through soldering, and the lower surface of the second circuit connection portions 62 and the upper surface of the lands 43 serving as the second circuit are conductively connected to each other through soldering. This configuration allows for, in addition to a first heat dissipation path along which the heat generated in the body portion 34 of the electronic component 30 is transferred to the conductive member 44 via the lower surface electrode 33 and the first circuit connection portion 61, a second heat dissipation path along which heat is transferred to the lands 43 via the lower surface electrode 33, the first circuit connection portion 61, and the second circuit connection portion 62. Accordingly, it is possible to enhance the heat dissipation performance,

As shown in FIGS. 1 and 4, the first circuit connection portion 61 of the heat spreader 60 is sized to substantially comfortably fit in the first opening 45. Accordingly, simply placing the first circuit connection portion 61 in the first opening 45 brings the heat spreader 60 into the proper connection orientation, thus facilitating mounting of the heat spreader 60 to the circuit board 40. In addition, the body portion 34 of the electronic component 30 is sized to substantially comfortably fit between the pair of intermediate connection portions 63. Accordingly, simply placing the body portion 34 between the pair of intermediate connection portions 63 brings the electronic component 30 into a proper connection orientation, thus facilitating mounting of the electronic component 30 to the heat spreader 60.

As shown in FIG. 1, a second opening 46 smaller than the first opening 45 is provided at a position of the circuit board 40 at which the first electrode 31 of the electronic component 30 is to be mounted. The second opening 46 is provided continuously with the first opening 45, and the first opening 45 and the second opening 46 together as a whole constitute a single opening. Similarly to the first opening 45, the second opening 46 extends vertically through the circuit board 40 so as to allow the conductive member 44 disposed on the first surface 42 to be exposed on the second surface 41 side.

A relay terminal 70 is disposed in the second opening 46. Similarly to the heat spreader 60, the relay terminal 70 is formed by for example, pressing a metal plate of copper or the like into a predetermined shape. Accordingly, the first electrode 31 of the electronic component 30 is conductively connected to the conductive member 44 of the first circuit via the relay terminal 70. More specifically, the relay terminal 70 is connected to the upper surface of the conductive member 44 exposed in the second opening 46 through soldering, and the first electrode 31 of the electronic component 30 is connected to the upper surface of the relay terminal 70 through soldering. Consequently, the conductive member 44 serving as the first circuit and the lands 43 serving as the second circuit are connected to each other by the relay terminal 70.

Even more specifically the relay terminal 70 includes a fitting recess 71 that substantially comfortably fits in the second opening 46, and a pair of bulging portions 72 are disposed along the second surface 41 of the circuit board 40. Accordingly, simply fitting the fitting recess 71 into the second opening 46 so as to be placed on the upper surface of the conductive member 44 enables the relay terminal 70 to be positioned in a proper mounting orientation relative to the circuit board 40. Furthermore, although not shown, the pair of bulging portions 72 are placed on the pair of lands 43 serving as the second circuit. This facilitates mounting of the relay terminal 70 to the circuit board 40.

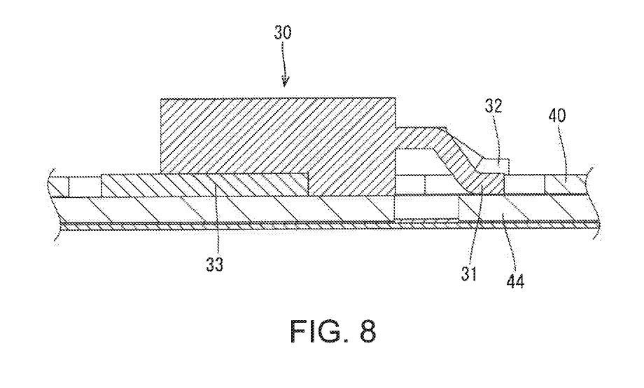

The thickness of the fitting recess 71 of the relay terminal 70 is set to be the same as the thickness of the circuit board 40. Therefore, the upper surface of the fitting recess 71 and the upper surface of the lands 43 serving as the second circuit are at the same height. In doing so, the lower surface of the first electrode 31 and the lower surface of the second electrode 32 will inevitably be disposed at the same height in the thickness direction of the circuit board 40. That is, for a conventional circuit structure that does not include the relay terminal 70, it is necessary to intentionally process the first electrode 31 to be located at a relatively low position compared with the second electrode 32 so as to come into contact with the conductive member 44, as shown in FIG. 8. In contrast, such processing does not need to be performed in Embodiment 1.

As described above, in Embodiment 1, the lower surface electrode 33 of the electronic component 30 is conductively connected to the first circuit (conductive member 44) via the thermally conductive conducting member (heat spreader 60), and is also conductively connected to the second circuit (pair of lands 43). Since the heat generated in the electronic component 30 dissipates to both the first circuit and the second circuit via the thermally conductive conducting member, it is possible to enhance the heat dissipation performance compared with that achieved by dissipating heat only to the first circuit as in the conventional technique. Therefore, it is possible to ensure the heat dissipation performance even for an electronic component 30 with a reduced size.

The first circuit may be disposed on the first surface 42 of the circuit board 40, the second circuit may be disposed on the second surface 41 of the circuit board 40, and the circuit board 40 may have the first opening 45 that allows the first circuit to be exposed on the second surface 41 side, and the first circuit connection portion 61 may be provided so as to extend along the first circuit inside the first opening 45.

This configuration facilitates mounting of the thermally conductive conducting member to the circuit hoard 40 since it is only necessary to place the first circuit connection portion 61 of the thermally conductive conducting member on the first circuit exposed in the first opening 45.

The second circuit connection portion 62 may be provided so as to extend along the second surface 41 of the circuit board 40, and the first circuit connection portion 61 and the second circuit connection portion 62 may be connected via the intermediate connection portion 63.

This configuration facilitates mounting of the thermally conductive conducting member to the circuit board 40 since it is only necessary to place the second circuit connection portion 62 on the second circuit.

The intermediate connection portions 63 may have a crank-like shape extending from the first circuit, through the peripheral edge portion of the first opening 45, to the second circuit.

This configuration facilitates mounting of the thermally conductive conducting member to the circuit board 40 since it is only necessary to place the intermediate connection portion 63 so as to extend from the first circuit to the second circuit.

The circuit board 40 may have the second opening 46 that allows the first circuit to be exposed on the second surface 41 side, the electronic component 30 may include the first electrode 31 connected to the first circuit via the relay terminal 70 disposed in the second opening 46, and the second electrode 32 to be connected to the second circuit, and the first electrode 31 and the second electrode 32 may be disposed at the same height in the thickness direction of the circuit board 40.

With this configuration, the first electrode 31 is connected to the first circuit via the relay terminal 70. Accordingly, the first circuit and the second circuit can be connected to each other without processing the first electrode 31 to conform to the height of the first circuit, even when they have different heights. In addition, the heat generated in the electronic component 30 will dissipate to both the first circuit and the second circuit via the relay terminal 70, and it is therefore possible to further enhance the heat dissipation performance.

### Embodiment 2

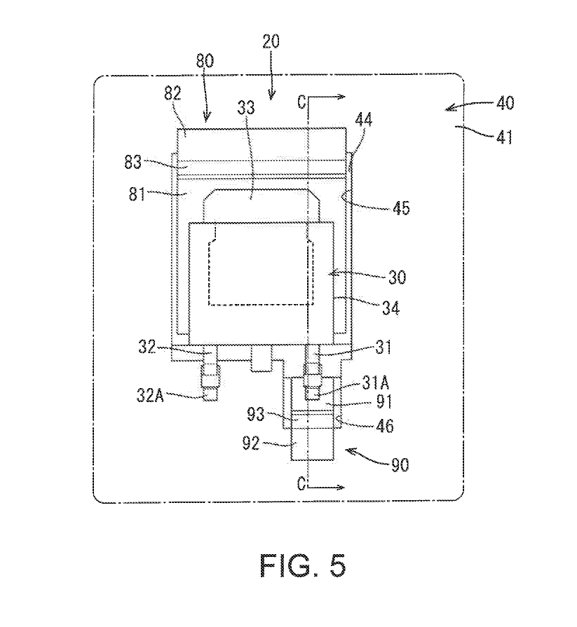

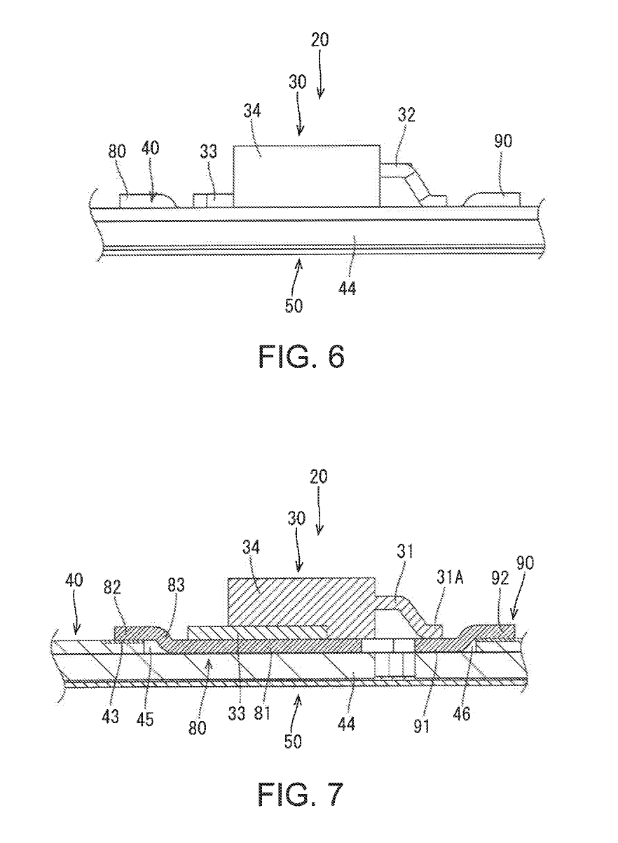

Next, Embodiment 2 will be described with reference to FIGS. 5 to 7. A circuit structure 20 according to Embodiment 2 is formed by partially changing the configurations of the heat spreader 60 and the relay terminal 70 of the circuit structure 10 according to Embodiment 1, and the other configurations are the same as those of Embodiment 1. Therefore, the description of the configurations, operations, and effects that overlap those of Embodiment 1 has been omitted. In addition, components that are the same as those of Embodiment 1 are denoted by the same reference numerals.

A heat spreader 80 according to Embodiment 2 includes a first circuit connection portion 81 to be connected to the conductive member 44 serving as the first circuit, a second circuit connection portion 82 to be connected to the lands 43 serving as the second circuit, and an intermediate connection portion 83 that connects the first circuit connection portion 81 and the second circuit connection portion 82. That is, whereas two second circuit connection portions 62 and two intermediate connection portions 63 are provided in Embodiment 1, one second circuit connection portion 82 and one intermediate connection portion 83 are provided in Embodiment 2.

While the second circuit connection portion 62 is provided so as to extend in a direction orthogonal to the direction of extension of the first electrode 31 and the second electrode 32 in Embodiment 1, the second circuit connection portion 82 and the intermediate connection portion 83 are provided so as to extend in the same direction as the direction of extension of the first electrode 31 and the second electrode 32 in Embodiment 2.

As described above, the configuration according to Embodiment 2 has the advantage of being able to reduce the sizes of the heat spreader 80 and the relay terminal 90 when a heat dissipation performance as high as that achieved by Embodiment 1 is not required. Although the arrangement of the lands 43 may vary depending on the type of the circuit pattern of the circuit board 40, the heat spreader 80 and the relay terminal 90 according to Embodiment 2 are advantageous in that the heat spreader 80 and the relay terminal 90 can be freely disposed according to the positions of the lands 43, regardless of the type of circuit pattern.

The relay terminal 90 according to Embodiment 2 includes a fitting recess 91 that substantially comfortably fits in the second opening 46, and a bulging portion 92 disposed along the second surface 41 of the circuit board 40. Accordingly, simply fitting the fitting recess 91 into the second opening 46 so as to be placed on the upper surface of the conductive member 44 allows the relay terminal 90 to be positioned in a proper mounting orientation relative to the circuit board 40. Although not shown, the bulging portion 92 is connected to the lands 43 serving as the second circuit through soldering. Consequently, the conductive member 44 serving as the first circuit and the lands 43 serving as the second circuit are connected to each other by the relay terminal 90.

### Other Embodiments

The present disclosure is not limited to the embodiments described by the above statements and drawings, and, for example, the following embodiments also fall within the technical scope of the present invention.

(1) Although the electronic component 30 includes one each of the first electrode 31, the second electrode 32, and the lower surface electrode 33 in Embodiments 1 and 2, the electronic component 30 may include two or more each of these components.

(2) In Embodiments 1 and 2, the first circuit connection portion 61 to be connected to the conductive member 44 serving as the first circuit and the electronic component connection portion to be connected to the lower surface electrode 33 of the electronic component 30 are provided at the same position. However, the electronic component connection portion may be provided at a position different from the first circuit connection portion 61.

(3) Two second circuit connection portions 62 are provided in Embodiment 1, and two second circuit connection portions 82 are provided in Embodiment 2. However, the number, shape and the like of the second circuit connection portion are not limited, and three second circuit connection portions may be provided, for example.

(4) in Embodiments 1 and 2, the first circuit connection portions 61 and 81 and the second circuit connection portions 62 82 are connected via the intermediate connection portions 63 and 83, respectively. However, end portions of the first circuit connection portions 61 and 81 and end portions of the second circuit connection portions 62 and 82 may be placed on top of each other so as to directly connect the first circuit connection portions 61 and 81 to the second circuit connection portions 62 and 82, respectively

(5) Although an example in which the first opening 45 and the second opening 46 are continuous is shown in Embodiments 1 and 2, the first opening and the second opening may be provided so as to be separate from each other.

(6) Although the thicknesses of the heat spreaders 60 and 80 and the thickness of the circuit board 40 are the same in Embodiments 1 and 2, they may not necessarily be the same.

(7) Although the transistor (FET) is shown as an example of the electronic component in Embodiments 1 and 2, the present invention may be applied to an electronic component such as a packaged component.

### LIST OF REFERENCE NUMERALS

10, 20 Circuit structure

30 Electronic component

31 First electrode

32 Second electrode

33 Lower surface electrode

40 Circuit board

41 Second surface

42 First surface

43 Land (second circuit)

44 Conductive member (first circuit)

45 First opening

46 Second opening

60, 80 Heat spreader (thee ally conductive conducting member)

61, 81 First circuit connection portion (electronic component connection portion)

62, 82 Second circuit connection portion

63, 83 Intermediate connection portion

70, 90 Relay terminal

1. A circuit structure comprising:
an electronic component including a lower surface electrode;
a circuit board including a first circuit and a second circuit; and
a thermally conductive conducting member to be disposed between the lower surface electrode of the electronic component and the first circuit,
wherein the thermally conductive conducting member includes an electronic component connection portion to be conductively connected to the lower surface electrode of the electronic component, a first circuit connection portion to be conductively connected to the first circuit, and a second circuit connection portion to be conductively connected to the second circuit.

2. The circuit structure according to claim 1,
wherein the first circuit is disposed on a first surface of the circuit board, the second circuit is disposed on a second surface of the circuit board, and the circuit board has a first opening configured to expose the first circuit to the second surface side, and
the first circuit connection portion is provided so as to extend along the first circuit inside the first opening.

3. The circuit structure according to claim 1,
wherein the second circuit connection portion is provided so as to extend along the second surface of the circuit board, and the first circuit connection portion and the second circuit connection portion are connected to each other via an intermediate connection portion.

4. The circuit structure according to claim 3,
wherein the intermediate connection portion has a crank-like shape extending from the first circuit, through a peripheral edge portion of the first opening, to the second circuit.

5. The circuit structure according to claim 1,
wherein the circuit board has a second opening configured to expose the first circuit to the second surface side,
the electronic component includes a first electrode connected to the first circuit via a relay terminal disposed in the second opening, and a second electrode to be connected to the second circuit, and
the first electrode and the second electrode are disposed at the same height in a thickness direction of the circuit board.

6. The circuit structure according to claim 2
wherein the second circuit connection portion is provided so as to extend along the second surface of the circuit board, and the first circuit connection portion and the second circuit connection portion are connected to each other via an intermediate connection portion.

7. The circuit structure according to claim 6,
wherein the intermediate connection portion has a crank-like shape extending from the first circuit, through a peripheral edge portion of the first opening, to the second circuit.

8. The circuit structure according to any one of claim 7,
wherein the circuit board has a second opening configured to expose the first circuit to the second surface side,
the electronic component includes a first electrode connected to the first circuit via a relay terminal disposed in the second opening, and a second electrode to be connected to the second circuit, and
the first electrode and the second electrode are disposed at the same height in a thickness direction of the circuit board.
